(19) United States
(12) Patent Application Publication
(10) Pub. No.: US 2009/0277777 A1
(43) Pub. Date: Nov. 12, 2009

(54) COLD-PRESSED SPUTTER TARGETS

(75) Inventors: Markus Schultheis, Flieden (DE); Martin Weigert, Hanau (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W.C. Heraeus GmbH, Hanau (DE)

(21) Appl. No.: 12/296,462

(22) PCT Filed: May 30, 2007
(86) PCT No.: PCT/EP2007/004754

§ 371 Date: Oct. 8, 2008

(30) Foreign Application Priority Data
Jun. 1, 2006 (DE) 10 2006 026 005.8

(51) Int. Cl. C23C 14/00; C23C 14/14; B32B 27/04

(52) U.S. Cl. 204/192.1; 204/298.13; 156/242

(57) ABSTRACT

A sputter target includes a sputter material made of an alloy or a material mixture composed of at least two components which are in a state of thermodynamic disequilibrium. The components are compacted by an isostatic or uniaxial cold-pressing process.

### CROSS-REFERENCE TO RELATED APPLICATIONS

This application is a Section 371 of International Application No. PCT/EP2007/004754, filed May 30, 2007, which was published in the German language on Dec. 6, 2007, under International Publication No. WO 2007/137824 A1 and the disclosure of which is incorporated herein by reference.

### BACKGROUND OF THE INVENTION

The invention relates to a sputter target comprising a sputter material made of an alloy or material mixture comprising at least two components, as well as a method for its production.

Sputter targets for cathode sputtering are typically produced by melt-metallurgical methods or powder-metallurgical methods. Power-metallurgical methods are used, among other things, when the desired components cannot be alloyed by melt technology or when the resulting alloys have too great a brittleness to be brought to the desired target geometry.

Powder-metallurgical methods used up until now are:
cold pressing and sintering at elevated temperatures
hot axial pressing of the powder or powder mixtures
hot isostatic pressing of the powder or powder mixtures
powder swaging or powder rolling (as a rule in sealed cans)
plasma injection and thermal injection.

All of these typical methods have in common that the powders are heated considerably during the production process, partially above the melting point (German Patent Application Publication No. 41 15 663 A1), partially up to slightly below the melting point (e.g., sintering), or at least just under the melting point of the component with the lowest melting point (European Patent No. 0 243 995 B1, European Patent No. 0 834 594 B1). These thermally activated powder-metallurgical methods require, on one hand, a high apparatus expense, as, e.g., protective-gas furnaces, autoclaves, adequate, thermally stable pressing molds. On the other hand, this step of thermal powder compaction could lead to undesired secondary effects, such as oxidation or making the powder brittle through thermally activated solid-body reactions.

Recently, applications of sputter targets have been found, in which alloys or mixtures are in demand that are made of elements or components that contain, on one hand, extremely low melting point components and, on the other hand, high melting point components. Examples here are:

Cu/In or Cu/In/Ga alloys for photovoltaic semiconductors

Mixed targets comprising, on the one hand, low melting point elements, such as Sn, Zn, In, or Bi, on the other hand, components, such as silicon, titanium, niobium, manganese, or tantalum. The purpose of this mixed target is, e.g., to produce optically functional layers with selectively adjustable refractive indices, by reactive sputtering processes.

### BRIEF SUMMARY OF THE INVENTION

An object of the present invention is to provide a method for the most economical and qualitatively high value production of powder-metallurgical sputter targets and also to provide such sputter targets.

The object is achieved and advantageous embodiments emerge from the present description.

This object is achieved, among other things, in such a way that the two components of the sputter material exist in thermodynamic disequilibrium and are compacted by an isostatic or uniaxial cold-pressing method (that is, at or in the region of normal room temperature). The sputter material can be formed from elements/components which have a very large difference in the respective melting points. In particular, the components of the mixed target are produced in powder form. These powders are compacted by a cold-pressing method, as, e.g., cold axial pressing or cold isostatic pressing. The resulting pressed part is subjected to absolutely no thermal treatment (above room temperature), but instead is used as a sputter target directly, i.e., in the cold-pressed state, optionally after minimal cutting processing. This invention thus breaks with the paradigm, typically held until now, that sputter targets guarantee reliable functionality only when they have a stable compact structure at least due to sintering reactions. Surprisingly, it has been shown that for certain material combinations, extremely practical sputter targets can be produced through this cold-pressing process alone. It is particularly advantageous when the components are prepared in powder form in such a way that at least one component has a hardness of less than 100 MPa HB and this particularly soft component constitutes at least 20 vol. % of the sputter material. In addition to the possibility of pressing all of the metal components (pure metals or alloys) by this manner and means to form sputter targets, it is likewise possible to press composite targets from particularly soft metallic and hard ceramic components.

Preferably, at least one of the components is formed from at least one metal from the group: indium, tin, or bismuth or from an alloy based on these metals. In particular, at least one of the components can be formed from indium or from an indium-based alloy. It is beneficial that at least one of the components has a metallic purity of greater than 99.9%. The sputter material can be formed from the components:

a) indium or indium-based alloy

b) copper or copper-based alloy.

It can be arranged with a material fit on a carrier plate.

### DETAILED DESCRIPTION OF THE INVENTION

The method according to the invention is characterized in that the components are compacted by an isostatic or uniaxial cold-pressing method. Preferably, the components are not subjected to a thermal treatment after the cold pressing. It is advantageous that at least one of the components of the sputter material is pressed by an axial pressing method onto a metallic carrier plate and that a material-fit composite of the sputter material and carrier plate is formed. Also, at least one of the components of the sputter material could be pressed by an axial pressing method to form a target plate, and this target plate could be bonded or soldered onto a carrier plate separately from the pressing process. Here, the processing temperature of the bonding or soldering process can be lower than the lowest melting-point temperature of the components. The method can also be carried out in one variant, such that at least one of the components is pressed onto a carrier tube by an isostatic pressing method, and a material-fit composite is formed from the sputter material and carrier tube.

According to the method of the invention, planar sputter targets can be produced, in which they are pressed by an axial pressing method onto a metallic carrier plate. For this purpose, a surface-roughened carrier plate is preferably used and the powder mixture is pressed directly onto this carrier plate, so that a “microform-fit” composite is produced. Alternatively, according to this method, planar sputter targets can also be pressed into a plate made of target material, and the connection to a target-carrier plate can be produced at a later time by a bonding or solder connection.

According to the method of the invention, tubular cathodes can also be produced, in which the powder components are pressed as a mixture directly onto a roughened carrier tube by a typical cold isostatic pressing method.

Particularly good results are achieved when the “soft” component of the powder mixture comprises pure indium or an indium-based alloy. By this manner and means, for example, a Cu-In mixture can be produced for sputtering copper-indium-bearing thin-film photovoltaic films.

The invention will be explained below with reference to examples.

1. A mixture comprising 50 wt. % Si powder and 50 wt. % Sn powder, with respective grain sizes in a range of 10 μm to 140 μm (silicon) and 45 μm to 140 μm (tin), is compacted by cold axial pressing in a rectangular press mold (300×100 mm). On the bottom die of the press mold, a Cu plate of the size 300×100 mm is placed, which was roughened on its top side by sandblasting. After the powder was pressed at a pressure of 2000 bar in the axial direction onto the copper plate, a composite part is removed from the press mold, wherein the density of the compressed Si-Sn mixture has a density of 97% of the theoretical density. This composite part can be used as a cathode for sputter coating, wherein the copper plate of the composite system serves directly as a back plate for use in the sputter cathode.

2. A mixture comprising 60 wt. % indium and 40 wt. % copper, with respective grain sizes in a range of 5 μm to 200 μm, is pressed by cold axial pressing in a press mold with dimensions 300 ×100 mm at a pressure of 2000 bar. Both top and bottom dies of the pressing tool include ground steel plates. After the pressing process ends, a Cu-In composite plate can be removed from the pressing tool, wherein the density of this plate corresponds to approximately 99.5% of the theoretical density. This copper-indium plate is soldered by soft soldering onto a copper cathode plate using an Sn-In soft solder ( 50/50 wt. %) together with other plates produced by the same manner and means, so that a sputter cathode with dimensions 900×100 mm can be fitted. This sputter cathode is used for the production of copper-indium alloy films.

3. A mixture comprising 60 wt. % indium powder and 40 wt. % Cu-Ga alloy powder, wherein the alloy in turn comprises a Cu 70/Ga 30 alloy, is filled into a pressing tool. This pressing tool has an inner hollow core, which is made, for example, of stainless steel and which is to be used later as a carrier tube of a tubular sputter cathode. This inner hollow core carries, on its outside, a rough flame-sprayed coating, made of, e.g., Ni-Al alloy. The outer part of the pressing tool is comprises a rubber bag. After filling the intermediate space between the inner carrier tube and the outer rubber bag, the end faces of this cylindrical arrangement are sealed water-tight with rubber sealing compound. The powder mixture is then compressed in a cold isostatic press (CIP method) at 2000 bar pressing pressure on all sides. After the compaction step, the outer rubber bag is removed. The former powder mixture is now present as a compacted outer wall of a composite cylinder system. The outer diameter of this composite is processed with a turning method, so that a tube is produced with a homogeneous wall thickness. The Cu-In-Ga composite system on steel tube is then used as tubular cathodes for sputter technique production of Cu-Ga-In films.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1-15. (canceled)

16. A sputter target including a sputter material comprising an alloy or material mixture having at least two components, wherein the at least two components are present in thermodynamic disequilibrium and have been compacted by an isostatic or uniaxial cold-pressing method.

17. The sputter target according to claim 16, wherein a first component of the at least two components has a hardness of less than 100 MPa (Brinell hardness) and the first component comprises at least 20 vol. % of the alloy or material mixture.

18. The sputter target according to claim 16, wherein at least one of the at least two components is in a form of a powder.

19. The sputter target according to claim 16, wherein the at least two components comprise metals or alloys or a mixture of metal or alloy with ceramic material.

20. The sputter target according to claim 16, wherein at least one of the at least two components comprises at least one metal selected from the group consisting of indium, tin, bismuth, and an alloy of indium, tin, or bismuth.

21. The sputter target according to claim 16, wherein at least one of the at least two components comprises indium or an indium-based alloy.

22. The sputter target according to claim 16, wherein at least one of the at least two components has a metallic purity of greater than 99.9%.

23. The sputter target according to claim 16, wherein the at least two components comprise at least one component selected from the group consisting of indium or an indium-based alloy and copper or a copper-based alloy.

24. The sputter target according to claim 16, wherein the sputter material is arranged with a material fit on a carrier plate or on a carrier tube.

25. A method for producing the sputter target according to claim 16, comprising compacting the at least two components by an isostatic or uniaxial cold pressing.

26. The method according to claim 25, wherein the at least two components are not subjected to any thermal treatment after the cold pressing.

27. The method according to claim 25, wherein the at least two components are compacted by uniaxial cold pressing onto a metallic carrier plate to form a material-fit composite comprising the sputter material and carrier plate.

28. The method according to claim 25, wherein the at least two components are compacted by uniaxial cold pressing onto a target plate, and the target plate is then bonded or soldered onto a carrier plate.

29. The method according to claim 28, wherein the bonding or soldering is carried out at a process temperature which is lower than a lowest melting-point temperature of any of the at least two components.

30. The method according to claim 25, wherein the at least two components are compacted by isostatic cold pressing onto a carrier tube to form a material-fit composite of the sputter material and carrier tube.

31. A method of sputtering, comprising using the sputter target according to claim 16 to conduct sputtering.
